(19) United States
(12) Patent Application Publication
(10) Pub. No.: US 2026/0247779 A1
(43) Pub. Date: Aug. 20, 2026

(54) ELECTRODE MOUNTING STRUCTURES WITH THERMAL PATHWAYS FOR LIGHT-EMITTING DIODE DEVICES

(71) Applicant: CreeLED, Inc., Durham, NC (US)

(72) Inventors: David Suich, Durham, NC (US); Timothy Ling, Raleigh, NC (US); Everett Bradford, Apex, NC (US); Ryan Mohn, Mebane, NC (US); Colin Blakely, Raleigh, NC (US)

(21) Appl. No.: 19/057,216

(22) Filed: Feb. 19, 2025

(51) Int. Cl. H10H 29/85; H10H 29/853; H10W 90/00

(52) U.S. Cl. CPC H10H 29/857; H10H 29/853; H10W 90/00

(57) ABSTRACT

Light-emitting diode (LED) devices and more particularly electrode mounting structures with thermal pathways for LED devices are disclosed. An exemplary electrode mounting structure for an LED device includes a support element with a metal core or base, a dielectric layer, and one or more mounting pads. At least one of the mounting pads forms at least a portion of a direct thermal and electrically conductive path through the dielectric layer to the metal core of the support element. An LED chip is mounted and electrically connected to the mounting pad that forms at least a portion of a direct thermal and electrically conductive path, thereby providing a continuous electrical and thermal pathway from the LED chip to the metal core that avoids dielectric interfaces.

### FIELD OF THE DISCLOSURE

The present disclosure relates to light-emitting diode (LED) devices, and more particularly to electrode mounting structures with thermal pathways for LED devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to electrode mounting structures with thermal pathways for LED devices. An exemplary electrode mounting structure for an LED device includes a support element with a metal core or base, a dielectric layer, and one or more mounting pads. At least one of the mounting pads forms at least a portion of a direct thermal and electrically conductive path through the dielectric layer to the metal core of the support element. An LED chip is mounted and electrically connected to the mounting pad that forms at least a portion of a direct thermal and electrically conductive path, thereby providing a continuous electrical and thermal pathway from the LED chip to the metal core that avoids dielectric interfaces.

In one aspect, an LED device comprises: a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and a first LED chip mounted to the support element and electrically coupled to the first mounting pad and the second mounting pad, the first LED chip comprising a first bond pad that is mounted and electrically coupled to the first mounting pad. In certain embodiments, the first LED chip further comprises a second bond pad that is mounted and electrically coupled to the second mounting pad. In certain embodiments, the first LED chip further comprises a second bond pad that is electrically coupled to the second mounting pad by a wire bond. The LED device may further comprise a second LED chip mounted to the support element, wherein the support element further comprises a third mounting pad and a fourth mounting pad, the third mounting pad forming part of another direct thermal and electrical path through the dielectric layer to the metal core, and a first bond pad of the second LED chip is mounted and electrically coupled to the third mounting pad. In certain embodiments: a second bond pad of the first LED chip is electrically connected to the second mounting pad by way of a wire bond; and a second bond pad of the second LED chip is mounted to and electrically connected to the fourth mounting pad. The LED device may further comprise an electrical component that is different from an LED, the electrical component mounted to and electrically coupled to an electrical component mounting pad of the support element, the electrical component mounting pad forming part of another direct thermal and electrical path through the dielectric layer to the metal core. In certain embodiments, the electrical component comprises a thermistor. In certain embodiments, the first LED chip is one of a plurality of LED chips, and each LED chip of the plurality of LED chips is electrically and thermally connected to the metal core. The LED device may further comprise: a retention ring on the support element, the retention ring extending around a perimeter of the plurality of LED chips; and an encapsulant contained by the retention ring, the encapsulant positioned to cover the plurality of LED chips; wherein a topside package bond pad is positioned on a surface of the support element that is outside the retention ring. In certain embodiments, a portion of the first mounting pad forms another topside package bond pad such that the first mounting pad is electrically addressable from a topside and a bottom side of the support element.

The LED device may further comprise a second LED chip mounted to the support element, wherein: the support element further comprises a third mounting pad; a first bond pad of the second LED chip is mounted and electrically coupled to the second mounting pad; a second bond pad of the second LED chip is mounted and electrically coupled to the third mounting pad; and a second bond pad of the first LED chip is electrically connected to the second mounting pad.

The LED device may further comprise a second LED chip mounted to the support element, wherein: the support element further comprises a third mounting pad and a fourth mounting pad, the third mounting pad forming part of another direct thermal and electrical path through the dielectric layer to the metal core; a first bond pad of the second LED chip is electrically coupled to the fourth mounting pad; a second bond pad of the second LED chip is mounted and electrically coupled to the third mounting pad; and a second bond pad of the first LED chip is electrically connected to the second mounting pad.

In another aspect, an LED module comprises: a board; and a plurality of LED devices on the board, each LED device of the plurality of LED devices comprising: a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and a first LED chip mounted to the support element and electrically coupled to the first mounting pad and the second mounting pad, the first LED chip comprising a first bond pad that is mounted and electrically coupled to the first mounting pad. In certain embodiments, a first LED device of the plurality of LED devices is electrically connected to a second LED device of the plurality of LED devices by a jumper connection. In certain embodiments, the board comprises an insulating layer, and the support element for each LED device of the plurality of LED devices is on the insulating layer.

In another aspect, an LED fixture comprises: a housing; and an LED device mounted on the housing, the LED device comprising: a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and a first LED chip mounted to the support element and electrically coupled to the first mounting pad and the second mounting pad, the first LED chip comprising a first bond pad that is mounted and electrically coupled to the first mounting pad. The LED fixture may further comprise: a second LED chip mounted to the support element, wherein the support element further comprises a third mounting pad and a fourth mounting pad, the third mounting pad forming part of another direct thermal and electrical path through the dielectric layer to the metal core, and a first bond pad of the second LED chip is mounted and electrically coupled to the third mounting pad. The LED fixture may further comprise a power source within the housing, wherein the housing forms an electrically conductive path between the metal core and the power source. In certain embodiments, the power source is connected to driver electronics for driving the LED device. In certain embodiments, the power source, the driver electronics, the housing, and the LED device form a flashlight.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) device where one or more LED chips are mounted to a support element.

FIG. 2 is a cross-sectional view of an LED device similar to the LED device of FIG. 1 for embodiments that further include an electrical component or circuit element mounted to the support element.

FIG. 3A is a top view of an LED package similar to the LED device of FIG. 2.

FIG. 3B is a bottom view of the LED package of FIG. 3A.

FIG. 4 is a top view of an LED package similar to the LED package of FIGS. 3A and 3B for embodiments with a large array of the LED chips.

FIG. 5 is a cross-sectional view of an LED device similar to the LED device of FIG. 1 for embodiments with a combination of vertical and flip-chip structures for first and second LED chips.

FIG. 6 is a cross-sectional view of an LED device similar to the LED device of FIG. 5 for embodiments where the second LED chip is not connected to a direct thermal and electrical path to the metal core.

FIG. 7 is a cross-sectional view of an LED device similar to the LED device of FIG. 6 for embodiments where the first and second LED chips are electrically coupled in series.

FIG. 8 is a cross-sectional view of an LED device similar to the LED device of FIG. 7 for embodiments where the first and second LED chips are electrically coupled in series by way of the metal core.

FIG. 9 is a cross-sectional view of an LED device similar to the LED device of FIG. 8 for additional embodiments where the first and second LED chips are electrically coupled in series by way of the metal core.

FIG. 10 is a cross-sectional view of an LED module that includes multiple smaller LED devices similar to the LED devices described above for FIGS. 1 to 9.

FIG. 11 is a cross-sectional view of a lighting device, such as a flashlight, that includes an LED device according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to electrode mounting structures with thermal pathways for LED devices. An exemplary electrode mounting structure for an LED device includes a support element with a metal core or base, a dielectric layer, and one or more mounting pads. At least one of the mounting pads forms at least a portion of a direct thermal and electrically conductive path through the dielectric layer to the metal core of the support element. An LED chip is mounted and electrically connected to the mounting pad that forms at least a portion of a direct thermal and electrically conductive path, thereby providing a continuous electrical and thermal pathway from the LED chip to the metal core that avoids dielectric interfaces.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB.

Encapsulant materials, such as silicone, epoxy, or polymethyl methacrylate (PMMA), among others, may be formed to encapsulate the LED chips over a submount. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

LED devices, such as LED chips and LED packages, are susceptible to damage and/or impaired operation with excess heat. Heat may be generated by the LED device during operation where an electrically activated LED chip forms a heat source. Conventional LED packages include LED chips electrically mounted to traces of submounts or lead frame structures. The submounts or lead frame structures may then be mounted and electrically coupled to another support element, such as a printed circuit board. In certain applications, LED packages may further include neutral thermal pads on their backsides that are thermally coupled to thermal pathways of the printed circuit board that are not electrically active. In such arrangements, a first interface is typically formed between LED chips and submounts or lead frame structures and another interface is formed between the submount or lead frame structure and the printed circuit board. Each interface, particularly where insulating materials may be present provides thermal interfaces that provide some barriers to thermal flow.

According to aspects of the present disclosure, an electrical contact of an LED chip is mounted and electrically coupled to a pad of a printed circuit board that forms a direct thermal path to a metal core of the printed circuit board. By bonding and electrically coupling the LED chip in this manner, various dielectric interfaces may be removed, thereby permitting increased thermal flow. As such, LED chips may be operated at increased power while maintaining safe operating temperatures.

FIG. 1 is a cross-sectional view of an LED device 10 where one or more LED chips 12-1, 12-2 are mounted to a support element 14. For illustrative purposes, two LED chips 12-1, 12-2 are shown, but the principles described are applicable to any number of LED chips 12-1, 12-2, including a single LED chip or a larger array of LED chips. The support element 14 may form a printed circuit board having a metal core 16, a dielectric layer 18, and various mounting pads 20-1 to 20-4. The metal core 16 may comprise copper (Cu), Al, and/or alloys thereof, among others. The dielectric layer 18 may comprise an epoxy resin reinforced with glass, such as FR4, among others. The mounting pads 20-1 and 20-3 form parts of direct thermal and electrical pathways through the dielectric layer 18 to the metal core 16. The mounting pads 20-2, 20-4 form electrically conductive traces that are electrically isolated from the metal core 16. Each LED chip 12-1, 12-2 includes a first bond pad 22 and a second bond pad 24. The first bond pad 22 forms either the anode pad or the cathode pad while the second bond pad 24 forms the other of the anode pad or the cathode pad. The following description is provided in the context of the first bond pad 22 forming the cathode pad and the second pond pad 24 forming the anode pad, but the principles are equally applicable to the reverse configuration. The LED device 10 may embody an LED package, an LED display, an LED fixture, or part of an LED board or module that is connected within an LED display or an LED fixture.

The first bond pad 22 for the LED chip 12-1 is mounted and electrically coupled to the first mounting pad 20-1, thereby forming an electrical and thermal path to the metal core 16 that is devoid of non-metallic interfaces. In a similar manner, the second bond pad 24 for the LED chip 12-2 is mounted and electrically coupled to the third mounting pad 20-3, thereby forming another electrical and thermal path to the metal core 16 that is devoid of non-metallic interfaces. In such an arrangement, increased thermal flow is permitted from the LED chips 12-1, 12-2 to the metal core 16. Additionally, the metal core 16 forms a common cathode connection for the LED chips 12-1, 12-2. By way of example, for embodiments where the LED chips 12-1, 12-2 generally have a turn-on voltage of three volts, the resulting LED device 10 forms a three-volt device where the metal core 16 is electrically active as the cathode connection. In the example of FIG. 1, the LED chips 12-1, 12-2 are flip-chip mounted to the support element 14. As such, the second bond pads 24 are respectively mounted and electrically coupled to the mounting pads 20-2, 20-4. One or more anode connections for the LED device 10 may be made to or provided by the mounting pads 20-2, 20-4. For embodiments where the LED chips 12-1, 12-2 are individually addressable, the mounting pads 20-2, 20-4 form separate anode connections. For embodiments where the LED chips 12-1, 12-2 are electrically coupled in parallel, the mounting pads 20-2, 20-4 may be connected to form a common anode connection for the LED device 10.

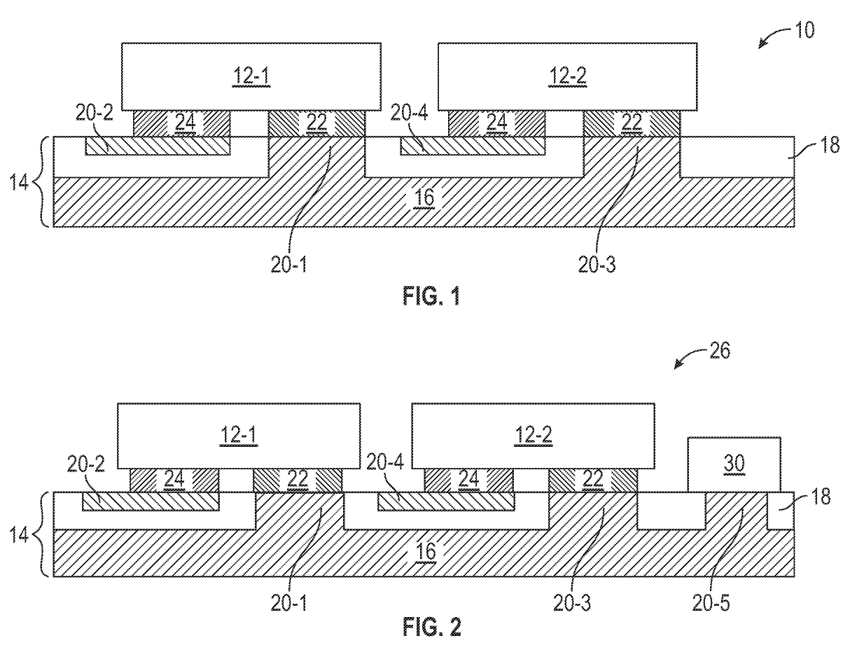

FIG. 2 is a cross-sectional view of an LED device 26 similar to the LED device 10 of FIG. 1 for embodiments that further include an electrical component 30 or circuit element mounted to the support element 14. The electrical component 30 may embody a circuit element that does not generate light, such as one or more of an electrostatic discharge device, a thermistor, and/or various drive electronics, such as one or more of a current regulator, or a switch, such as a metal–oxide–semiconductor field-effect transistor (MOSFET), among others. The electrical component 30 may be electrically mounted and thermally connected to a mounting pad 20-5 of the support element 14. In such embodiments, the mounting pad 20-5 may also be referred to as an electrical component mounting pad. As with the mounting pads 20-1, 20-3, the mounting pad 20-5 forms part of a direct electrical and thermal path to the metal core 16. Accordingly, the electrical component 30 may also be electrically connected to the same common cathode, or anode in the alternative, as the LED chips 12-1, 12-2. For embodiments where the electrical component 30 comprises a thermistor, the direct thermal and electrical path to the metal core 16 may advantageously provide the thermistor with improved temperature accuracy of the metal core 16.

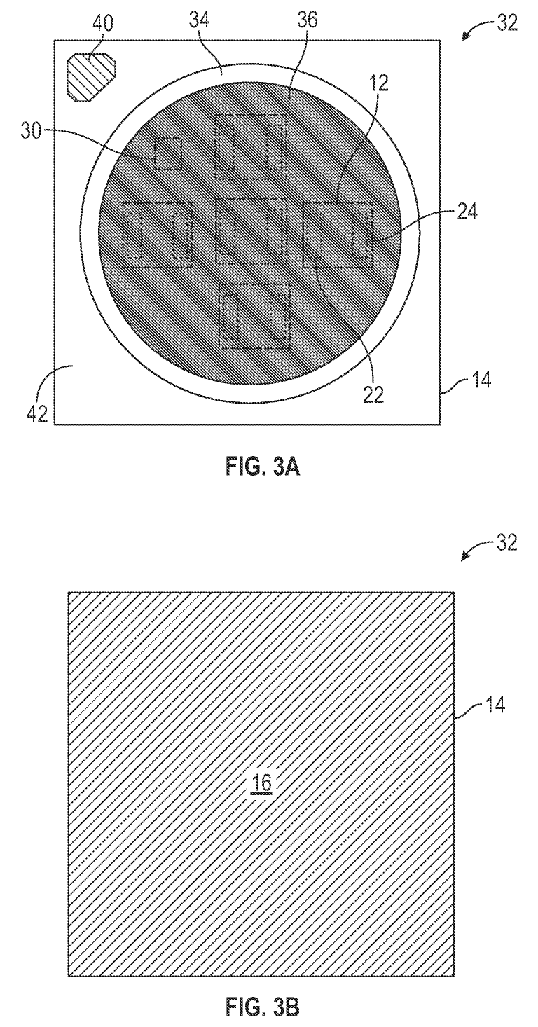

FIG. 3A is a top view of an LED package 32 similar to the LED device 26 of FIG. 2. FIG. 3B is a bottom view of the LED package 32 of FIG. 3A. For package-level structures, the support element 14 may form a submount of the LED package 32. From the top view, multiple LED chips 12, with respective first and second bond pads 22, 24, form an array on the support element 14. The LED chips 12 may be connected to corresponding mounting pads as illustrated in FIG. 2, where the first bond pads 22 for each LED chip 12 are connected to a corresponding mounting pad that provides part of a direct thermal and electrical path to the metal core 16. In certain embodiments, the LED package 32 may include a retention ring 34 that extends around a perimeter of the array of LED chips 12. The retention ring 34 may embody a light-altering material configured to reflect light from the LED chips 12. By way of example, the retention ring 34 may comprise a white material, such as silicone embedded with TiO₂. An encapsulant 36 may be contained by the retention ring 34 such that the encapsulant 36 covers the LED chip 12. In certain embodiments, the encapsulant 36 may comprise a lumiphoric material, such as a binder of silicone embedded with phosphor particles. For illustrative purposes, locations of the LED chips 12 and first and second bond pads 22, 24 under the encapsulant 36 are shown in dashed lines. In certain embodiments, the electrical component 30 as described above with respect to FIG. 2 is also shown in dashed lines under the encapsulant 36. The mounting pads 20-2, 20-4 of FIG. 2 that are not electrically connected to the metal core 16 may be electrically connected to a topside package bond pad 40 that is positioned to receive an external electrical connection, such as from a wire bond. In certain embodiments, a light-altering material layer 42 is formed on the top surface of the support element 14 for further light reflection. The light-altering material layer 42 may embody a solder mask that covers portions of the support element 14 outside the retention ring 34 while also leaving a top surface of the topside package bond pad 40 uncovered. As best illustrated in FIG. 3B, the metal core 16 is positioned to form at least a portion of a bottom side package bond pad for mounting and electrically connecting the LED package 32 to another device.

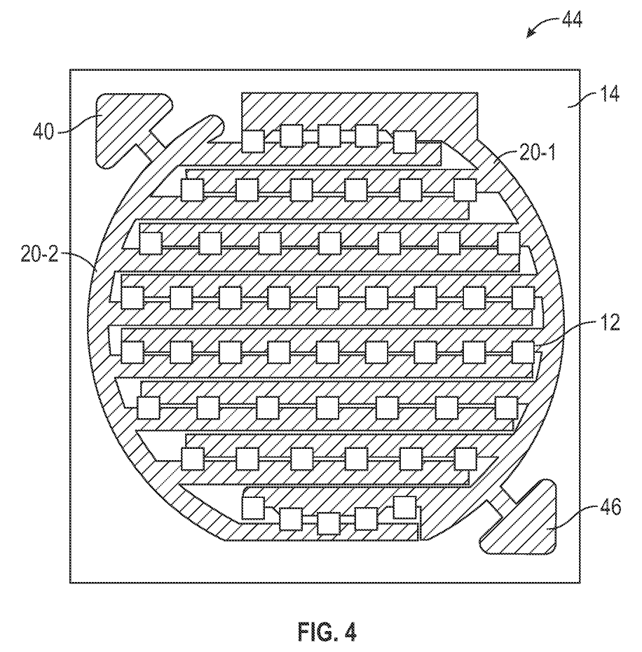

FIG. 4 is a top view of an LED package 44 similar to the LED package 32 of FIGS. 3A and 3B for embodiments with a large array of the LED chips 12. The mounting pads 20-1, 20-2 form two patterned traces on a top side of the support element 14. The mounting pads 20-1, 20-2 each form a number of extensions that are interdigitated with one another to provide multiple die attach areas for the LED chips 12. As illustrated, each LED chip 12 is mounted and electrically connected to the mounting pads 20-1, 20-2 to provide anode and cathode connections. Such an arrangement is similar to the flip-chip configuration of the LED device 10 of FIG. 1. In FIG. 4, the topside package bond pad 40 is part of the mounting pad 20-2 and is positioned to facilitate a topside electrical contact by way of a wire bond. As described with respect to FIGS. 1 to 3B, the mounting pad 20-1 may form part of a direct thermal and electrical path to the metal core 16 on the bottom side of the LED package 44. Additionally, a portion of the mounting pad 20-1 may extend and form another topside package bond pad 46. The topside package bond pad 46 provides the ability to make an electrical connection to the mounting pad 20-1 by way of another wire bond connection, in addition to being able to make an electrical connection to the mounting pad 20-1 by way of the metal core 16 of FIG. 3B. Such versatility allows the LED package 44 to be used in a variety of applications where the mounting pad 20-1 is electrically addressable from both the top side and the bottom side of the support element 14.

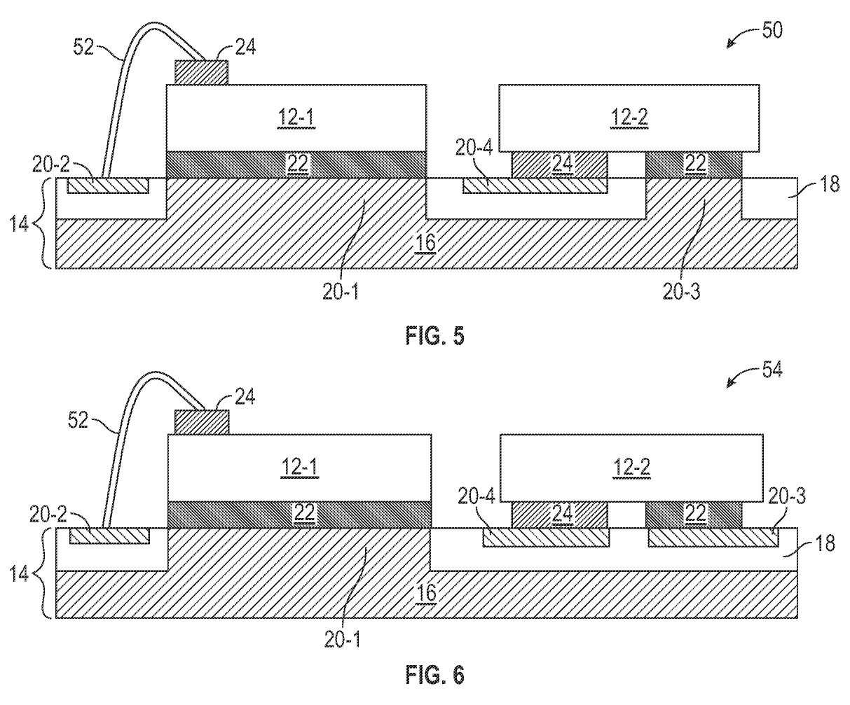

The principles described above with respect to direct thermal and electrical paths in support elements for LED devices and LED packages provide flexibility in electrical connections for multiple LED chip embodiments. Various combinations of serial or parallel arrangements may be formed with direct thermal and electrical paths to metal cores of support elements. Additionally, various combinations of LED chip structures, such as LED chips with vertical contact structures and LED chips with flip-chip structures, may be arranged within a same LED device or LED package. FIGS. 5 to 9 provide various examples of such configurations.

FIG. 5 is a cross-sectional view of an LED device 50 similar to the LED device 10 of FIG. 1 for embodiments with a combination of vertical and flip-chip structures for first and second LED chips 12-1, 12-2. The first LED chip 12-1 in FIG. 5 embodies a vertical contact structure where the first bond pad 22 and the second bond pad 24 are on opposing sides of the LED chip 12-1. The first bond pad 22 is mounted and electrically connected to the mounting pad 20-1 which also forms the direct thermal and electrical path to the metal core 16. The second bond pad 24 of the LED chip 12-1 is connected to the mounting pad 20-2 by way of a wire bond 52. The second LED chip 12-2 embodies a flip-chip structure where both of its first and second bond pads 22, 24 are on a same side and mounted to the support element 14. The first bond pad 22 of the second LED chip 12-2 is mounted and electrically connected to the mounting pad 20-3, which also forms another direct thermal and electrical path to the metal core 16. In certain embodiments, the first LED chip 12-1 may be configured with an active LED structure including AlInGaP to generate red light. AlInGaP and related LED chip structures are known to have the worst thermal droop compared with other material systems, such as GaN-based structures common for blue and green LED chips. In this manner, the LED chip 12-1 may embody a red LED chip with a direct thermal and electrical path to the metal core 16 by way of the mounting pad 20-1 for improved thermal performance. The LED chip 12-2 may embody a blue or green emitting chip, with or without lumiphoric materials.

FIG. 6 is a cross-sectional view of an LED device 54 similar to the LED device 50 of FIG. 5 for embodiments where the second LED chip 12-2 is not connected to a direct thermal and electrical path to the metal core 16. As illustrated, the first LED chip 12-1 is arranged the same way as described above for FIG. 5. The third and fourth mounting pads 20-3, 20-4 for the second LED chip 12-2 are isolated from the metal core 16 by way of the dielectric layer 18. As described above, different LED chip structures may have different thermal requirements. Accordingly, not all LED chips (e.g., 12-2 in FIG. 6) are electrically connected to direct thermal paths to the metal core 16 in certain embodiments.

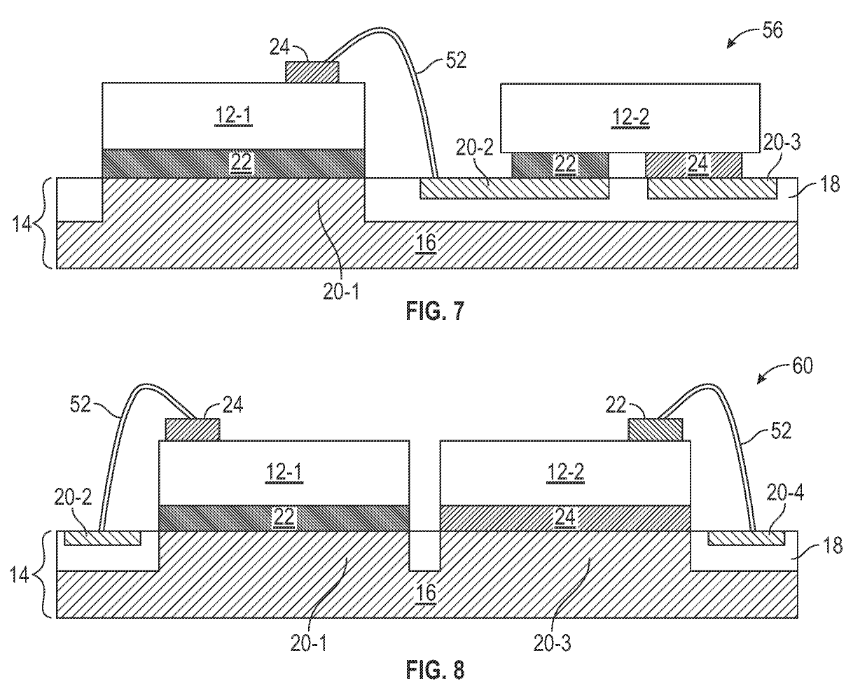

FIG. 7 is a cross-sectional view of an LED device 56 similar to the LED device 54 of FIG. 6 for embodiments where the first and second LED chips 12-1, 12-2 are electrically coupled in series. As illustrated, the second bond pad 24 of the first LED chip 12-1 may be electrically connected to the first bond pad 22 of the second LED chip 12-2. This may be accomplished by mounting the first bond pad 22 of the second LED chip 12-2 to the mounting pad 20-2, and connecting the wire bond 52 between the mounting pad 20-2 and the second bond pad 24 of the first LED chip 12-1.

FIG. 8 is a cross-sectional view of an LED device 60 similar to the LED device 56 of FIG. 7 for embodiments where the first and second LED chips 12-1, 12-2 are electrically coupled in series by way of the metal core 16. As illustrated, the first and third mounting pads 20-1, 20-3 of FIG. 8 form part of two direct thermal and electrical paths to the metal core 16. The first bond pad 22 of the first LED chip 12-1 is mounted to the first mounting pad 20-1, and the second bond pad 24 of the second LED chip 12-2, having opposite polarity to the first bond pad 22, is mounted to the third mounting pad 20-3. Accordingly, the first and second LED chips 12-1, 12-2 are electrically coupled in series with electrical and thermally pathways through the metal core 16.

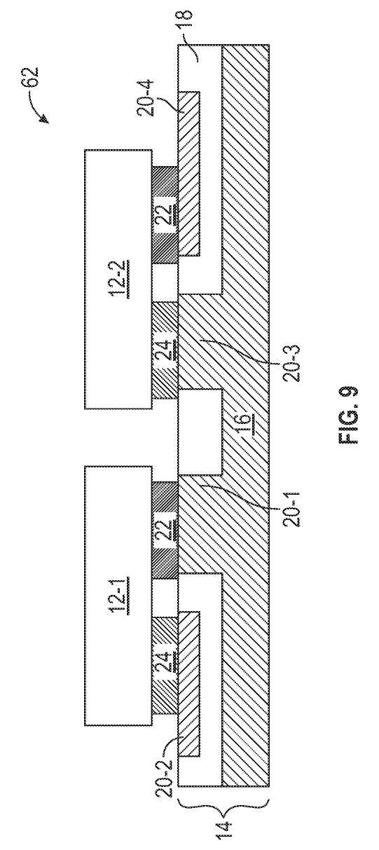

FIG. 9 is a cross-sectional view of an LED device 62 similar to the LED device 60 of FIG. 8 for additional embodiments where the first and second LED chips 12-1, 12-2 are electrically coupled in series by way of the metal core 16. In FIG. 9, the first LED chip 12-1 is flip-chip mounted to the first mounting pad 20-1 and the second mounting pad 20-2, and the second LED chip 12-2 is flip-chip mounted to the third mounting pad 20-3 and the fourth mounting pad 20-4. As with FIG. 8, the direct electrical and thermally conductive paths at least partially formed by the first mounting pad 20-1 and the third mounting pad 20-3 provide a serial connection for the LED chips 12-1, 12-2 by way of the metal core 16.

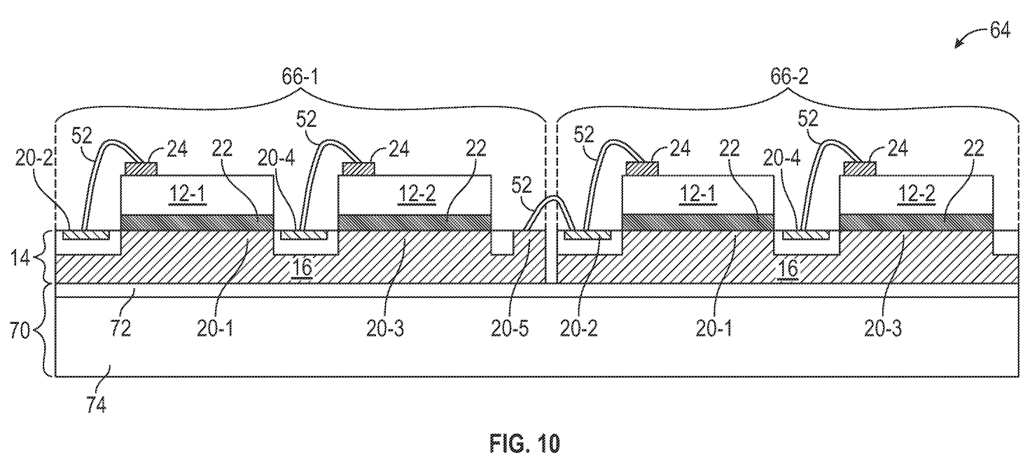

FIG. 10 is a cross-sectional view of an LED module 64 that includes multiple smaller LED devices 66-1, 66-2 similar to the LED devices described above for FIGS. 1 to 9. Any of the LED devices of FIGS. 1 to 9 may form modular units that can be arranged together to form a larger light-emitting surface area. For illustrative purposes, the LED module 64 is illustrated with two smaller LED devices 66-1, 66-2 arranged together on a board 70. Each LED device 66-1, 66-2 is shown with two LED chips 12-1, 12-2 for illustrative purposes. In practice, each LED device 66-1, 66-2 may include many more arrays of LED chips 12-1, 12-2. The first bond pad 22 of the first LED chip 12-1 is mounted and electrically coupled to the first mounting pad 20-1 that forms part of a direct electrical and thermally conductive path to the metal core 16 of the first LED device 66-1. The first bond pad 22 of the second LED chip 12-2 is mounted and electrically coupled to the third mounting pad 20-3 that forms part of another direct electrical and thermally conductive path to the metal core 16 of the first LED device 66-1. The second LED device 66-2 is substantially similar to the first LED device 66-1, except the first LED device 66-1 may include a fifth mounting pad 20-5 that facilitates a jumper connection to the second LED device 66-2 by way of a wire bond 52. Each LED device 66-1, 66-2 may be mounted to an insulating layer 72 of the board 70 since the metal cores 16 are electrically active. A base 74 of the board may comprise a heat sink for additional thermal dissipation. The LED module 64 may be a stand-alone component and/or form part of a larger LED package, an LED display, or an LED lighting fixture.

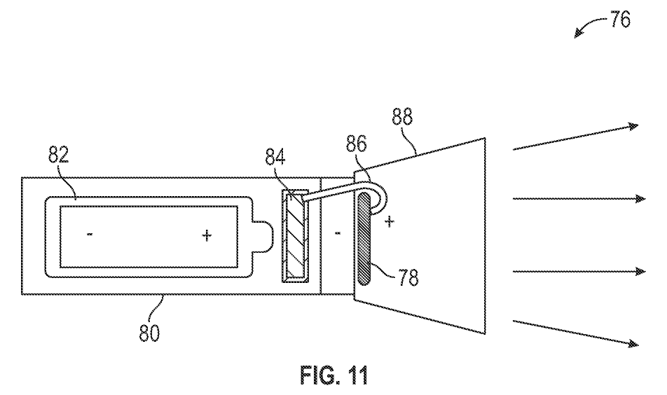

FIG. 11 is a cross-sectional view of a lighting device 76, such as a flashlight, that includes an LED device 78 according to principles of the present disclosure. The LED device 78 may embody any of the LED devices and/or modules described above for FIGS. 1 to 10. In this regard, the bottom side (facing the left in the orientation of FIG. 11) of the LED device 78 comprises the electrically active metal core 16 of any of FIGS. 1 to 10. As depicted in FIG. 11, the bottom side of the LED device 78 forms a negative electrode connection while the top side (facing to the right in the orientation of FIG. 11) forms a positive electrode connection. The lighting device 76 includes a housing 80 which contains a power source 82, such as battery, and driver electronics 84, such as a driver printed circuit board. Since the bottom side of the LED device 78 is electrically active by way of the metal core 16 of FIGS. 1 to 10, the housing 80 may advantageously form an electrically conductive housing that electrically couples to the negative terminal of the power source 82. A positive supply wire 86 is provided to electrically couple the top side of the LED device 78 to the driver electronics 84 and the positive terminal of the power source 82. With such a structure, the housing 80 may form both electrical and thermal pathways so that only a single supply wire (i.e., positive supply wire 86) is required, thereby simplifying wiring and machining of the lighting device 76. In the context of a flashlight, the lighting device 76 may be driven with higher power to generate more light out of a reflector 88, while maintaining safe operating temperatures for the LED device 78.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and
a first LED chip mounted to the support element and electrically coupled to the first mounting pad and the second mounting pad, the first LED chip comprising a first bond pad that is mounted and electrically coupled to the first mounting pad.

2. The LED device of claim 1, wherein the first LED chip further comprises a second bond pad that is mounted and electrically coupled to the second mounting pad.

3. The LED device of claim 1, wherein the first LED chip further comprises a second bond pad that is electrically coupled to the second mounting pad by a wire bond.

4. The LED device of claim 1, further comprising a second LED chip mounted to the support element, wherein the support element further comprises a third mounting pad and a fourth mounting pad, the third mounting pad forming part of another direct thermal and electrical path through the dielectric layer to the metal core, and a first bond pad of the second LED chip is mounted and electrically coupled to the third mounting pad.

5. The LED device of claim 4, wherein:
a second bond pad of the first LED chip is electrically connected to the second mounting pad by way of a wire bond; and
a second bond pad of the second LED chip is mounted to and electrically connected to the fourth mounting pad.

6. The LED device of claim 1, further comprising an electrical component that is different from an LED, the electrical component mounted to and electrically coupled to an electrical component mounting pad of the support element, the electrical component mounting pad forming part of another direct thermal and electrical path through the dielectric layer to the metal core.

7. The LED device of claim 6, wherein the electrical component comprises a thermistor.

8. The LED device of claim 1, wherein the first LED chip is one of a plurality of LED chips, and each LED chip of the plurality of LED chips is electrically and thermally connected to the metal core.

9. The LED device of claim 8, further comprising:
a retention ring on the support element, the retention ring extending around a perimeter of the plurality of LED chips; and
an encapsulant contained by the retention ring, the encapsulant positioned to cover the plurality of LED chips;
wherein a topside package bond pad is positioned on a surface of the support element that is outside the retention ring.

10. The LED device of claim 9, wherein a portion of the first mounting pad forms another topside package bond pad such that the first mounting pad is electrically addressable from a topside and a bottom side of the support element.

11. The LED device of claim 1, further comprising a second LED chip mounted to the support element, wherein:
the support element further comprises a third mounting pad;
a first bond pad of the second LED chip is mounted and electrically coupled to the second mounting pad;
a second bond pad of the second LED chip is mounted and electrically coupled to the third mounting pad; and
a second bond pad of the first LED chip is electrically connected to the second mounting pad.

12. The LED device of claim 1, further comprising a second LED chip mounted to the support element, wherein:
the support element further comprises a third mounting pad and a fourth mounting pad, the third mounting pad forming part of another direct thermal and electrical path through the dielectric layer to the metal core;
a first bond pad of the second LED chip is electrically coupled to the fourth mounting pad;
a second bond pad of the second LED chip is mounted and electrically coupled to the third mounting pad; and
a second bond pad of the first LED chip is electrically connected to the second mounting pad.

13. A light-emitting diode (LED) module comprising:
a board; and
a plurality of LED devices on the board, each LED device of the plurality of LED devices comprising:
a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and
a first LED chip mounted to the support element and electrically coupled to the first mounting pad and the second mounting pad, the first LED chip comprising a first bond pad that is mounted and electrically coupled to the first mounting pad.

14. The LED module of claim 13, wherein a first LED device of the plurality of LED devices is electrically connected to a second LED device of the plurality of LED devices by a jumper connection.

15. The LED module of claim 13, wherein the board comprises an insulating layer, and the support element for each LED device of the plurality of LED devices is on the insulating layer.

16. A light-emitting diode (LED) fixture comprising:
a housing; and
an LED device mounted on the housing, the LED device comprising:
a support element comprising a metal core, a dielectric layer on the metal core, a first mounting pad, and a second mounting pad, the first mounting pad forming part of a direct thermal and electrical path through the dielectric layer to the metal core, the second mounting pad being electrically isolated from the metal core; and
a first LED chip mounted to the support element and electrically coupled to the first mounting pad and the second mounting pad, the first LED chip comprising a first bond pad that is mounted and electrically coupled to the first mounting pad.

17. The LED fixture of claim 16, further comprising a second LED chip mounted to the support element, wherein the support element further comprises a third mounting pad and a fourth mounting pad, the third mounting pad forming part of another direct thermal and electrical path through the dielectric layer to the metal core, and a first bond pad of the second LED chip is mounted and electrically coupled to the third mounting pad.

18. The LED fixture of claim 16, further comprising a power source within the housing, wherein the housing forms an electrically conductive path between the metal core and the power source.

19. The LED fixture of claim 18, wherein the power source is connected to driver electronics for driving the LED device.

20. The LED fixture of claim 19, wherein the power source, the driver electronics, the housing, and the LED device form a flashlight.
